(19) United States
(12) Patent Application Publication
(10) Pub. No.: US 2007/0281461 A1
(43) Pub. Date: Dec. 6, 2007

(54) SEMICONDUCTOR DEVICE HAVING A CONTACT STRUCTURE WITH A CONTACT SPACER AND METHOD OF FABRICATING THE SAME

(75) Inventor: Yoon-Taek JANG, Seoul (KR)

Correspondence Address: MARGER JOHNSON & MCCOLLOM, P.C., 210 SW MORRISON STREET, SUITE 400, PORTLAND, OR, 97204, US

(73) Assignee: SAMSUNG ELECTRONICS CO., LTD., Gyeonggi-do (KR)

(21) Appl. No.: 11/735,357

(22) Filed: Apr. 13, 2007

(30) Foreign Application Priority Data
May 30, 2006 (KR) 2006-48920

(51) Int. Cl. H01L 21/4763; H01L 21/8242

(52) U.S. Cl. 438/622; 438/625; 438/253

(57) ABSTRACT

Methods of manufacturing a semiconductor device having reduced susceptibility to void formation between upper metal wiring layers and lower contact pads are provided. According to the methods, an etch shield layer is formed to protect contact pads from subsequent etch processes. Semiconductor devices manufactured according to the methods are also provided.

This U.S. non-provisional application claims the benefit of priority under 35 U.S.C.§119 from Korean Patent Application No. 2006-48920, filed on May 30, 2006, the entire contents of which are incorporated herein by reference.

### BACKGROUND

1. Technical Field

The disclosure relates to methods of fabricating semiconductor devices and devices fabricated according to these methods. Specifically, the disclosure relates to methods of forming contact structures used to connect active areas of semiconductor devices to upper metal layers. The disclosure also relates to semiconductor devices with contact structures fabricated according to the methods.

2. Description of the Related Art

Modern semiconductor devices typically include discrete devices such as transistors, resistors, and capacitors formed on a semiconductor substrate. Several layers of metallization can be required to connect the discrete devices to each other and to peripheral devices to form the desired circuitry. These layers of metallization require contact holes to penetrate the layers of interlayer insulating films that separate the metal layers.

As the degree of integration of semiconductor devices increases, the size and space available for formation of contact holes is correspondingly decreasing and, therefore, the process margins for forming the contacts also decreases. The ability to reliably form contact holes, i.e. the process margin, has an impact on the overall yield of a semiconductor device fabrication process. Consequently, efforts to improve the yield of semiconductor device fabrication processes must address the process margins available for contact formation.

FIGS. 1-5 are cross-sectional views illustrating a conventional method to form the contact structures for dynamic random access memory (DRAM) cells. As shown in FIG. 1, a device isolation layer 3 is formed in a predetermined area of a semiconductor substrate 1 to define first active areas 3a and second active areas 3b between the first active areas 3a. A first interlayer insulation film 5 is formed over the first active areas 3a, the second active areas 3b and the device isolation layer 3. The first interlayer insulation film 5 is then patterned to form a first pad contact hole and a second pad contact hole, which respectively exposes the first and second active areas 3a, 3b. The first conductive pads 7d and the second conductive pads 7b may then be formed within the first and second pad contact holes, respectively. The conductive pads 7d, 7b may be formed with doped polysilicon.

As shown in FIG. 2, the first interlayer dielectric layer 5 is recessed to expose the upper portions of the sidewalls of the first and second conductive pads 7d, 7b. Pad spacers 9 are formed adjacent to the exposed upper portions of the sidewalls of the first and second conductive pads 7d, 7b. The pad spacers 9 are formed of an insulating material that has etch selectivity relative to the conductive pads 7d, 7b and the first interlayer insulation film 5. For example, the pad spacers 9 may be formed of silicon nitride.

A second interlayer insulation film 11 is then formed over the first and second conductive pads 7d, 7b with the pad spacers 9. Direct contact holes 13 are formed to expose a region of the first conductive pads 7d by patterning of the second interlayer insulation film 11. The direct contact holes 13 have a smaller diameter than the width of the first conductive pads 7d to increase the overlap margin of wiring metallization that is formed to cover the contact holes 13 at subsequent processing steps. Because the diameter of the direct contact holes 13 is smaller than the width of the first conductive pads 7d, portions of the second conductive pads 7d between the contact holes 13 and the spacer 9 are necessarily exposed and thus vulnerable to the etchant in the subsequent processes as will be explained below.

Next, contact spacers 15 are formed on the sidewalls of the direct contact holes 13. A barrier metal layer 17 is formed over the entire surface of the substrate 1 that has the contact spacers 15. The barrier metal layer 17 is a double layer of titanium and titanium nitride layer. In this case, a metal silicide layer 17a, such as a titanium silicide layer, is formed at the interface between the barrier metal layer 17 and the first conductive pads 7d. This is due to the silicidation reaction between the two materials that form the barrier metal layer 17 and the first conductive pads 7d, as is known in the art.

Referring to FIG. 3, a metal wiring layer and a capping layer are consecutively formed over the resulting structure including the barrier metal layer 17. The metal wiring layer is formed of a metal such as tungsten and the capping layer is formed of an insulating material such as silicon nitride. A metal source gas such as WF₆ gas may be used to form the metal wiring layer, for example when the wiring metal layer is made of tungsten. The barrier metal layer 17 prevents the reaction of the metal source gas with the silicon atoms of the first conductive pads 7d.

The capping layer, the metal wiring layer, and the barrier metal layer 17 are patterned to form the first bit line patterns 22a that cover the direct contact holes 13 and also the second bit line pattern 22b between the first bit line patterns 22a. As a result, the first and second bit line patterns 22a, 22b are each formed to include a barrier metal layer pattern 17b, a metal wiring layer pattern 19, and a capping layer pattern 21.

Next, the bit line pattern spacers 23 are formed on the sidewalls of the bit line patterns 22a, 22b. The bit line pattern spacers 23 can be composed of the same material as the capping layer patterns 21. A third interlayer insulation film 25 is formed over the second interlayer insulation film 11, the first bit line patterns 22a, and the second bit line patterns 22b. The third interlayer insulation film 25 is then planarized to expose the capping layer patterns 21.

As shown in FIG. 4, the third interlayer insulation film 25 and the second interlayer insulation film 11 are patterned to form preliminary storage node contact holes 26, using the bit line patterns (22a, 22b) and the bit line pattern spacers 23 as a mask, thereby exposing the second conductive pads 7b.

As shown in FIG. 5, a wet etching process is performed on the resulting structure including the preliminary storage node contact holes 26. Accordingly, the final storage node contact holes 25a are formed, having an enlarged lower portion over the second conductive pads 7b. The wet etching process includes an isotropic etch of the second interlayer insulation film 11 to enlarge the lower portions of the final storage node contact holes 25a, and a cleaning process to remove etching residue, e.g., polymer material, from the surface of the second conductive pads 7b. The purpose of the wet etching process is to increase the process margin for forming the contacts to the second conductive pads 7b by increasing the exposed surface area of the pads 7b.

The wet etching process is performed using a chemical solution that etches the second interlayer insulation film 11. For example, the wet etching process can be performed using a chemical solution that contains a hydrofluoric acid solution (HF solution). In this case, the metal silicide layer 17a formed on the surface of the first conductive pads 7d may be exposed during the wet etching process. The exposed metal silicide layer 17a may be partially removed (e.g., to leave portion 17a′ remaining) or completely removed by the wet etching solution if it is exposed during the wet etching process. As a result, voids 17v may be formed under the barrier metal patterns 17b in the direct contact holes 13. These voids 17v may cause contact failures between the first wiring patterns 22a and the first conductive pads 7d. Contact failures such as these result in a diminished yield rate for the semiconductor devices.

Consequently, a method for forming contacts between the first wiring patterns 22a and the first conductive pads 7d that is not susceptible to void formation on the conductive pads is desired. This is particularly true when a diameter of the direct contact holes 13 is made to be smaller than the width of the first conductive pads 7d to increase the overlap margin of wiring metallization, thus leaving the top portion of the first conductive pads 7d, for example, between the direct contact holes 13 and the pad spacer 9 vulnerable to the etchant as illustrated in FIG. 5. Further, the method must be compatible with modern processes used to increase the overlap margin between the wiring metal patterns and the second conductive pads.

Accordingly, there is a need for novel contact structures that can prevent contact failures and the methods of forming such novel contact structures.

### SUMMARY

Embodiments of the invention provide a method of fabricating a semiconductor device, which is not susceptible to void formation between upper wiring metal patterns and lower contact pads. Embodiments provide an etch shield layer configured to prevent etch processes from forming voids between lower contact pads and upper wiring metal layers.

In one embodiment, an insulation layer is formed over a semiconductor substrate, the insulation layer having a conductive pad formed therein. A dielectric layer is formed on the insulation layer and the conductive pad. A region of the dielectric layer is etched to form a contact hole overlying the conductive pad, the contact hole exposing top corners of the conductive pad. An etch shield layer is formed within the contact hole, the etch shield layer covering the top corners of the conductive pad.

### BRIEF DESCRIPTION OF THE DRAWINGS

The above and other features and advantages of the invention will become more apparent by describing in detail exemplary embodiments thereof with reference to the following drawings.

FIG. 1 is a cross-sectional view of a semiconductor device illustrating contact pad formation.

FIG. 2 is a cross-sectional view of a semiconductor device illustrating barrier metal layer formation.

FIG. 3 is a cross-sectional view of a semiconductor device illustrating bit line pattern formation.

FIG. 4 is a cross-sectional view of a semiconductor device illustrating preliminary contact hole formation.

FIG. 5 is a cross-sectional view of a semiconductor device illustrating void formation between lower contact pads and upper wiring metal layer patterns.

FIG. 6 is a plan view of a DRAM cell array area suitable for use with embodiments of the invention.

FIGS. 7a through 14a are cross-sectional views corresponding to line I-I′ of FIG. 6 illustrating formation of the contact structure according to some embodiments of the invention.

FIGS. 7b through 14b are cross-sectional views corresponding to line II-II′ of FIG. 6 illustrating formation of the contact structure according to some embodiments of the invention.

FIGS. 15a through 19a are cross-sectional views corresponding to line I-I′ of FIG. 6 illustrating a manufacturing method according to some embodiments of the invention.

FIGS. 15b through 19b are cross-sectional views corresponding to line II-II′ of FIG. 6 illustrating a manufacturing method according to some embodiments of the invention.

### DETAILED DESCRIPTION

Exemplary embodiments of the disclosure will now be described more fully with reference to the accompanying drawings. The disclosure may, however, be embodied in many different forms and should not be construed as being limited to the embodiments set forth herein; rather, these embodiments are provided so that this disclosure will be thorough and complete, and will convey the concept of the disclosure to those skilled in the art. In the drawings, like reference numerals denote like elements, and the sizes and thicknesses of layers and regions are exaggerated for clarity. It will also be understood that when a layer is referred to as being “on” another layer or substrate, it can be directly on the other layer or substrate, or intervening layers may also be present. In the descriptions, like reference numerals denote like elements.

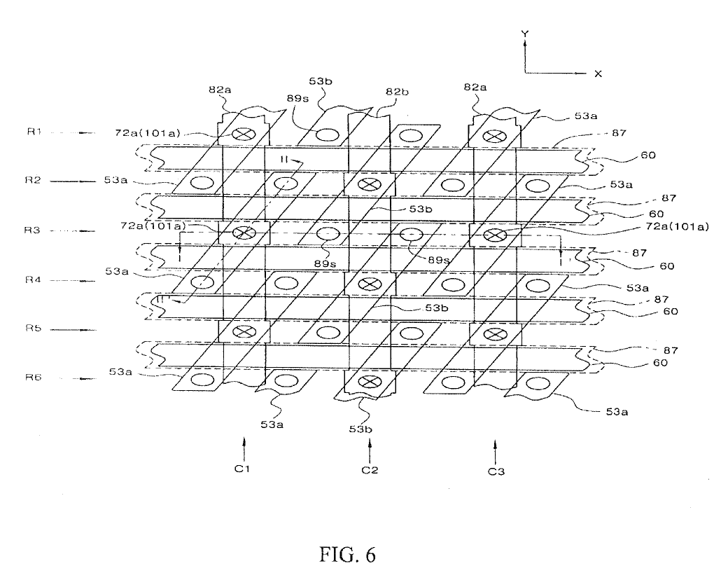

Referring to FIG. 6, a memory cell array area, e.g., a DRAM cell array area, includes word line patterns 60 that are extended parallel to the x axis. The first and the second bit line patterns, 82a and 82b cross the word line patterns 60. For example, the first and the second bit line patterns (82a, 82b) may be extended parallel to the y axis and perpendicular to the x axis. However, the present invention is not limited to this arrangement and one skilled in the art will appreciate that other positional relationships between the above elements are possible within the spirit and scope of the invention. For example, the first and second bit line patterns (82a, 82b) need not be perpendicular to the x axis.

The first bit line patterns 82a may correspond to odd-numbered columns and the second bit line patterns 82b may correspond to even-numbered columns. For example, the first bit line patterns 82a may correspond to the first column C1 and the third column C3, and the second bit line patterns 82b may correspond to the second column C2 and the fourth column (not shown). As a result, the second bit line patterns 82b are arranged in areas between the first bit line patterns 82a.

The DRAM cell array area further includes first active areas 53a and second active areas 53b, which are arranged to run parallel to each other. Also, each of the active areas (53a, 53b) may be arranged to cross one pair of word lines 60 and one bit line pattern (82a or 82b). The first and second active areas (53a, 53b) may not be parallel to either of the word line patterns 60 or the bit line patterns (82a, 82b). In other words, the first and second active areas (53a, 53b) may intersect the word line patterns 60 or the bit line patterns (82a, 82b) at an angle other than 90 degrees, e.g., less than 90 degrees.

The first bit line patterns 82a may cross the center portions of the first active areas 53a. The second bit line patterns 82b may cross the center portions of the second active areas 53b. Furthermore, centers portions of the first active areas 53a may be located at crossover points of odd-numbered lines (R1, R3, R5) and odd-numbered columns (C1, C3). Center portions of the second active areas 53b may be located at crossover points of even-numbered lines (R2, R4, R6) and even-numbered columns (C2). First contact holes 72a, also referred to as direct contact holes or bit line contact holes, may be located in center portions of the active areas (53a, 53b) and second contact holes 89s, also referred to as buried contact holes or storage node contact holes, may be located in both end portions of the active areas (53a, 53b).

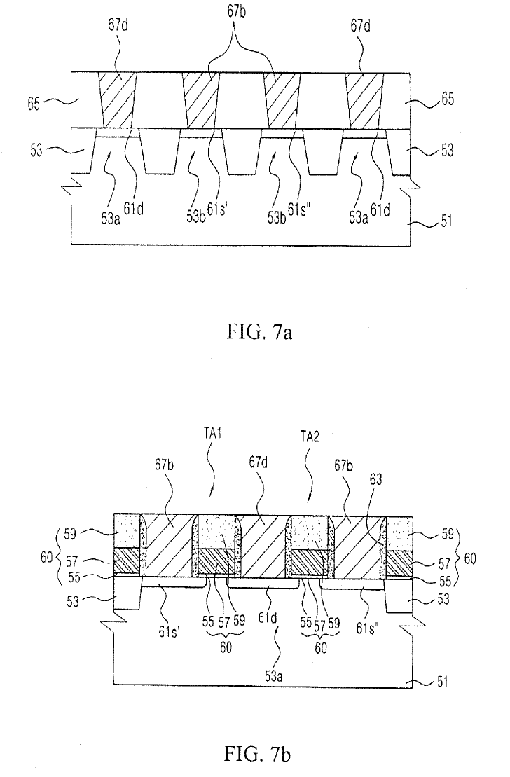

FIGS. 7a through 14a are cross-sectional views corresponding to line I-I′ (i.e., the word line direction) of FIG. 6 illustrating formation of the contact structure according to some embodiments of the invention. FIGS. 7b through 14b are cross-sectional views corresponding to line II-II′ (i.e., the active area direction) of FIG. 6 illustrating formation of the contact structure according to some embodiments of the invention.

Referring to FIGS. 7a and 7b, the first active area 53a and the second active area 53b are defined on a semiconductor substrate 51 using device isolation layers 53. The word line patterns 60, i.e., gate structures, are formed on the semiconductor substrate 51 between the device isolation layers 53. Also, impurity regions such as common drain areas 61d, first source area 61s′, and second source areas 61s″ are formed between the word line patterns 60 on the semiconductor substrate 51 using conventional techniques such as ion implantation. The word line patterns 60 each include a gate dielectric layer 55, a word line 57, a word line capping pattern 59, which are sequentially stacked on the semiconductor substrate 51. Word line pattern spacers 63 may be additionally formed on sidewalls of the word line patterns 60.

This process results in the formation of a first access transistor TA1 and a second access transistor TA2. The first access transistor TA1 includes the common drain area 61d, the first source area 61s′, the gate dielectric layer 55, and the word line 57. The second access transistor TA2 includes the common drain area 61d, the second source area 61s″, the gate dielectric layer 55 and the word line 57.

A first interlayer dielectric layer (or insulation layer) 65 is subsequently formed on the resulting structure including the word line patterns 60. The first interlayer dielectric layer 65 may be planarized by, for example, a chemical-mechanical polishing (CMP) process to expose a top surface of the word line capping patterns 59 of the word line patterns 60. Self-aligned contact holes are then formed in the first interlayer dielectric layer 65 using word line capping patterns 59 and the word line pattern spacers 63. The contact holes are filled with a conductive material to form first conductive pads 67d overlying the common drain area 61d and second conductive pads 67b overlying the first source area 61s′ or the second source area 61s″.

Referring to FIGS. 6, 7a, and 7b, first conductive pads 67d can correspond to the direct contact pads (bit line contact pads) of the DRAM cell array area. Second conductive pads 67b can correspond to the buried contact pads (storage node contact pads) of the DRAM cell array area. The first and second conductive pads 67d, 67b may be formed by using a self-aligned contact (SAC) technique.

According to some embodiments of the invention, the first and second conductive pads (67d, 67b) may include polysilicon.

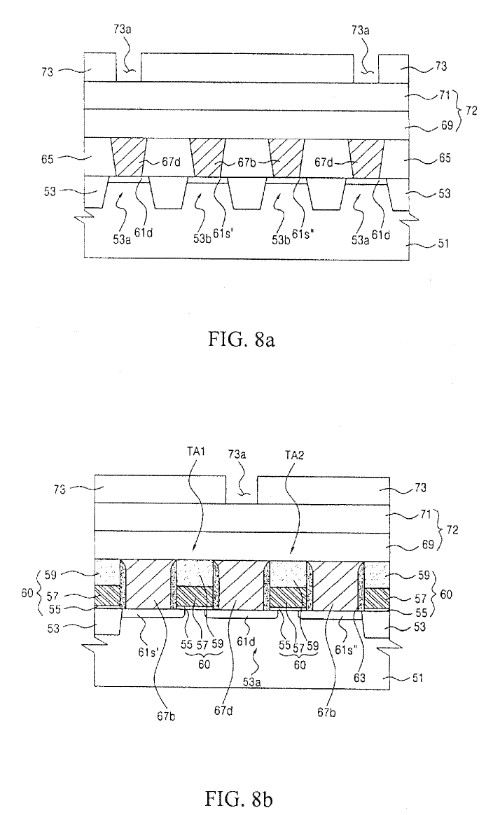

Referring to FIGS. 8a and 8b, a second interlayer dielectric layer 72 is formed on the substrate 51 having the first interlayer dielectric layer 65, the first and second conductive pads (67d, 67b), and the word line patterns 60. As illustrated, the second interlayer dielectric layer 72 may include a lower dielectric layer 69 and an upper dielectric layer 71 formed on the lower dielectric layer 69. The lower dielectric layer 69 may have an etch selectivity with respect to the upper dielectric layer 71. For example, the lower dielectric layer 69 may have a faster etch rate than the upper dielectric layer 71, i.e., the upper dielectric layer 71 having a lower etch rate than that of the lower dielectric layer 69.

According to some embodiments of the invention, the lower dielectric layer 69 and the upper dielectric layer 71 may be formed of a dielectric material such as boro-phospho-silicate glass (BPSG). The lower dielectric layer 69 may be formed of BPSG having a first boron concentration and the upper dielectric layer 71 may be formed of BPSG having a second boron concentration, where the second boron concentration is less than the first boron concentration. In this case, the lower dielectric layer 69 has a higher wet etching rate than the upper dielectric layer 71 if the upper and lower dielectric layers 69, 71 are exposed to an etching solution such as one including hydrofluoric acid (HF solution).

According to one aspect, a first photo-resist layer 73 may be formed on the upper dielectric layer 71. The first photo-resist layer 73 may then be patterned to form contact etch openings 73a exposing a region of the upper dielectric layer 71.

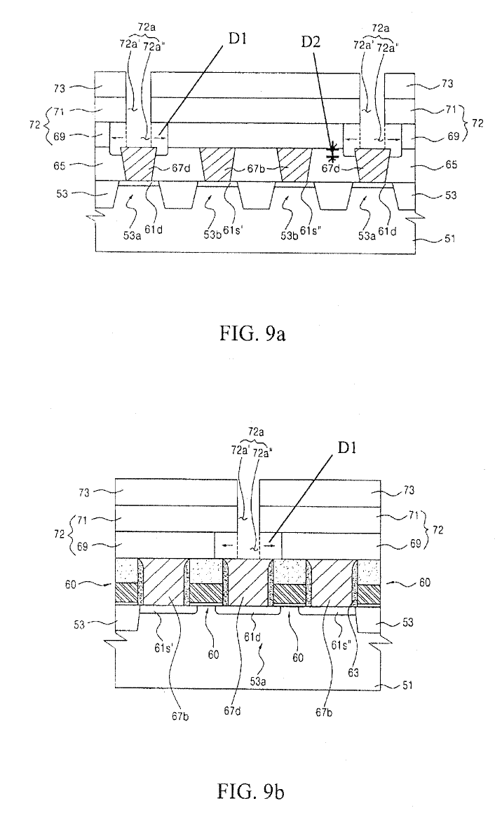

Referring to FIGS. 9a and 9b, the upper dielectric layer 71 and the lower dielectric layer 69 are etched to form the first contact holes 72a exposing at least a portion of the first conductive pads 67d. The first contact holes 72a, i.e., bit line contact holes, may include upper contact holes 72a′ and lower contact holes 72a″. As illustrated, a width of the upper contact holes 72a′ may be smaller than a width of the top portion (“an upper width”) of the first conductive pads 67d. And a width of the lower contact holes 72a″ may be larger than that the upper width of the first conductive pads 67d. Therefore, the first conductive pads 67d are exposed by the lower contact hole 72a″. According to one embodiment, the width of the lower contact hole 72a″ is wider width than the width of the upper contact hole 72a′. The relatively smaller width of the upper contact holes 72a′ desirably ensures an adequate alignment margin for wiring metal layers that cover the upper contact holes 72a′ in subsequent processing steps.

However, the present invention may not be limited to this if the alignment margin can be secured in the subsequent processing steps. For example, the upper contact holes 72a′ may have width substantially equal to that of the lower contact holes 72a″.

In one embodiment, the first contact holes 72a may be formed according to a multi-step etching process. For example, an anisotropic etch process forms a preliminary contact hole in the upper and lower dielectric layers 71, 69. The bottom portion of the preliminary contact hole (i.e., the portion of the preliminary contact hole formed in the lower dielectric layer 69) formed by the anisotropic etch process has an initial sidewall profile as indicated with the dotted lines shown in FIGS. 9a and 9b. The preliminary contact hole exposes a top portion of the first conductive pads 67d. Then, a subsequent isotropic etch process enlarges the width of the bottom portion of the preliminary contact hole by an amount D1, for example, at least 5 nm, to form lower contact holes 72a″. In one embodiment, the isotropic etch process may be a timed-etch process. In another embodiment, the isotropic etch process may be a wet-etch process and include, for example, an oxide etching solution that contains hydrofluoric acid (HF solution). In yet another embodiment, the isotropic etch process may also increase the depth of the preliminary contact hole to form a lower contact hole 72a″ that extends into the first interlayer dielectric layer 65 and below the top surface of the first conductive pads 67d by an amount of D2, for example, about 5 nm or more, thereby exposing an upper portion of the sidewalls of the first conductive pads 67d.

As a result of the multi-step etching process, the lower contact holes 72a″ are formed to expose substantially the entire top surface of the first conductive pads 67d and, in another embodiment, also expose upper sidewalls of the first conductive pads 67d as shown in FIG. 9a. As shown in FIG. 9a, an upper portion of the preliminary contact hole formed in the upper dielectric layer 71 defines the upper contact holes 72a′.

In another embodiment, the lower contact holes 72a″ may be formed so as to not extend into the first interlayer dielectric layer 65. Thus, the isotropic etching process may form lower contact holes 72a″ that do not, or only very slightly, extend into the first interlayer dielectric layer 65 while exposing substantially the entire top surface of the first conductive pads 67d. In this case, although not shown, a conductive pad spacer may be formed along upper sidewalls of the first conductive pads 67d to protect the first conductive pads 67d from etchant used during the isotropic etching process. This would be particularly helpful, if a silicide layer is formed along sidewalls of the first conductive pads 67d.

According to some embodiments, the first photo-resist layer 73 may be removed before the lower dielectric layer 69 is exposed to the isotropic etch process.

According to some other embodiments, the top surface of the first conductive pads 67d may be substantially level with the top surface of the gate capping pattern 59 in a cross sectional view along the active area direction. In this case, the upper sidewalls of the first conductive pads 67d may not be fully exposed by the enlarged lower contact holes 72a″.

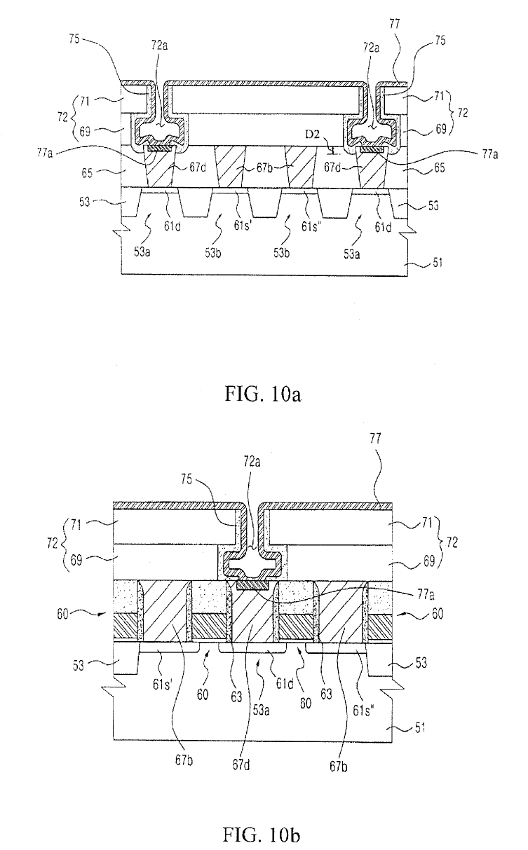

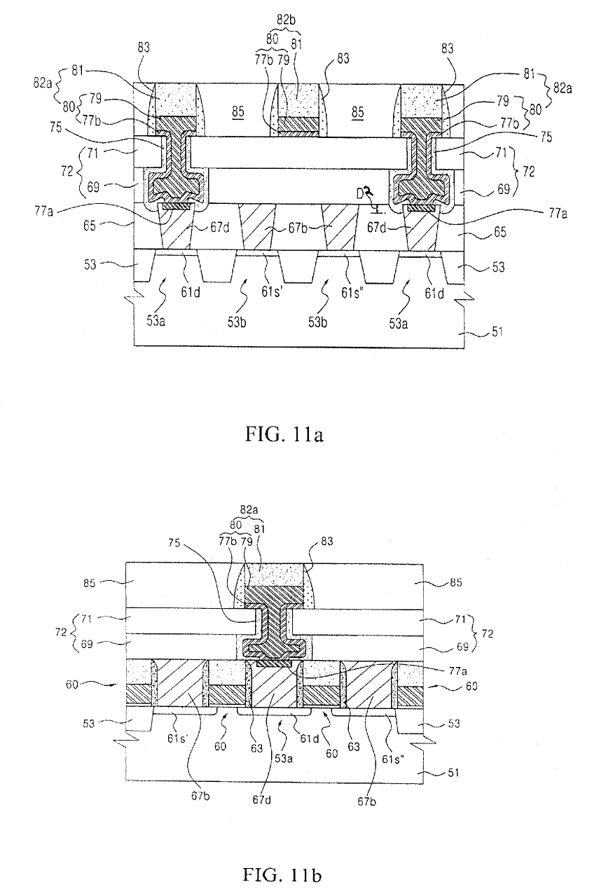

Referring to FIGS. 10a and 10b, an etch shield layer 75 is then formed on the resulting structure having the first contact hole 72a so as to cover the side walls of the first contact hole 72a and to cover portions of the first conductive pads 67d exposed by the first contact hole 72a where electrical contact is not desired (e.g., at peripheral regions of the top surface of the first conductive pads 67d and, in some embodiments, also at upper sidewalls of the first conductive pads 67d). For example, an etch shield material can be conformally deposited within the first contact hole 72a and subsequently etched to expose portions of the top surface of the first conductive pads 67d where electrical contact is desired (i.e., at contact regions of the first conductive pads 67d). Thus, the etch shield layer 75 may be seen to have an opening exposing a center region of the first conductive pads 67d surrounded by the peripheral regions.

The etch shield layer 75 may have a thickness of about 50 to about 300 angstroms. The etch shield layer 75 may comprise, for example, a silicon nitride material formed using a conventional Chemical Vapor Deposition (CVD) process. A barrier metal layer 77 is then formed on the etch shield layer 75, the upper dielectric layer 71, and the exposed top surface of the first conductive pads 67d. The barrier metal layer 77 may include, for example, a titanium material. At this point, a metal silicide layer 77a may be formed in the top surface of the first conductive pads 67d due to the reaction of the metal atoms of the barrier metal layer 77 with the silicon atoms in the first conductive pads 67d.

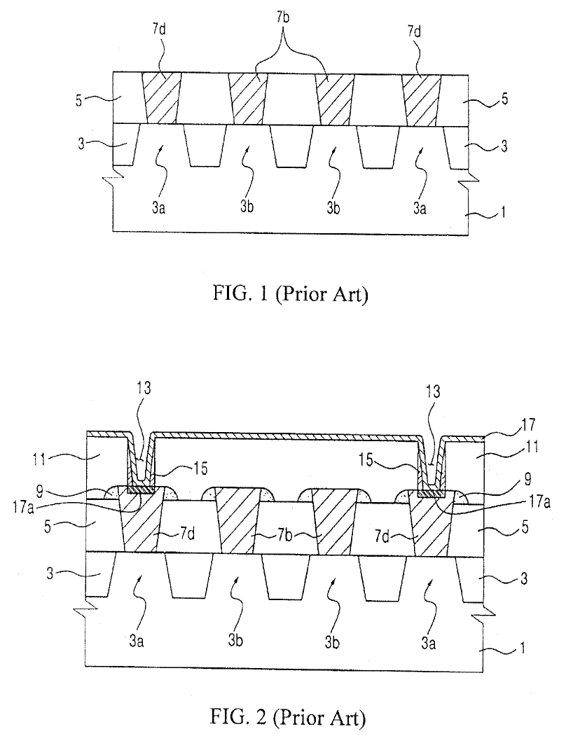

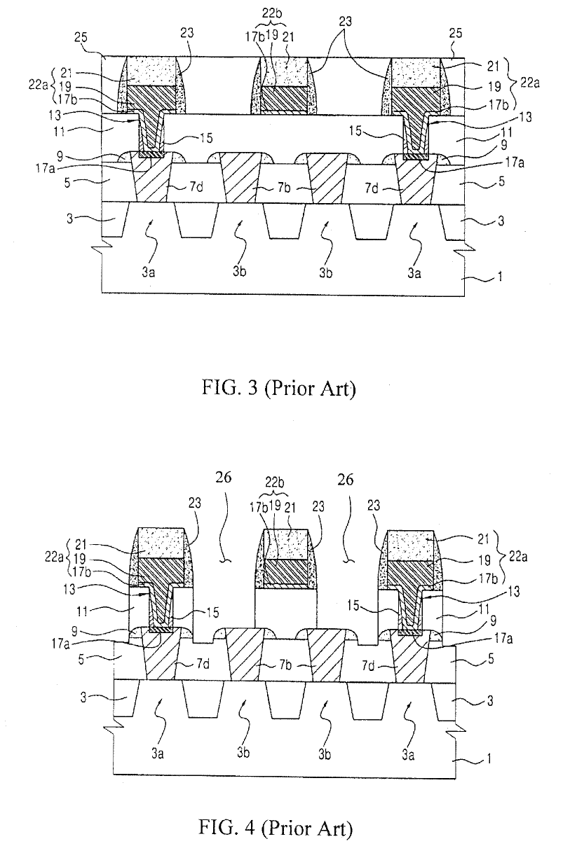

According to some embodiments, the depth D2 may be larger than the thickness of the metal silicide layer 77a. Consequently, the lowest part of the etch shield layer 75 that covers upper corners of the first conductive pads 67d (i.e., peripheral regions of the top surface of the contact pads 67d and/or the upper sidewalls of the first contact pads 67d) may be lower at least than the extent of the metal silicide layer 77a into the first conductive pads 67. In this case, even if the metal silicide layer 77a extends to the edge of the conductive pad 67d, the metal silicide layer will be covered and protected by the etch shield layer 75, even when the metal silicide layer is formed along sidewalls of the conductive pad 67d. As a result, compared to the prior art methods, the pad spacers 9 shown in FIG. 2 need not be separately formed in accordance with an aspect of the present invention, thereby simplifying the overall processing steps.

Referring to FIGS. 11a and 11b, a wiring metal layer and a wiring capping layer are formed over the barrier metal layer 77. In detail, the wiring metal layer may be formed to fill the first contact hole 72a surrounded by the barrier metal layer 77. The wiring capping layer, the wiring metal layer, and the barrier metal layer 77 are sequentially patterned to form a first bit line pattern 82a, which includes a bit line 80 and a bit line capping pattern 81, and a second bit line pattern 82b. Thus, portions of the upper dielectric layer 71 are exposed. The bit line 80 includes a barrier metal layer pattern 77b and a wiring metal layer pattern 79. A bit line pattern spacer 83 may be formed on sidewalls of the first bit line pattern 82a. The wiring metal layer may include a metal film such as a tungsten film and the wiring capping layer may include an insulating film such as a silicon nitride layer. If the wiring metal layer includes a tungsten film, a metal source gas such as WF₆ may be used to form the wiring metal layer using a conventional CVD process. Accordingly, the barrier metal layer 77 prevents the reaction of the WF₆ gas with silicon atoms of the first conductive pads 67d. A third interlayer dielectric layer 85 is then formed on the exposed portions of the upper dielectric layer 71.

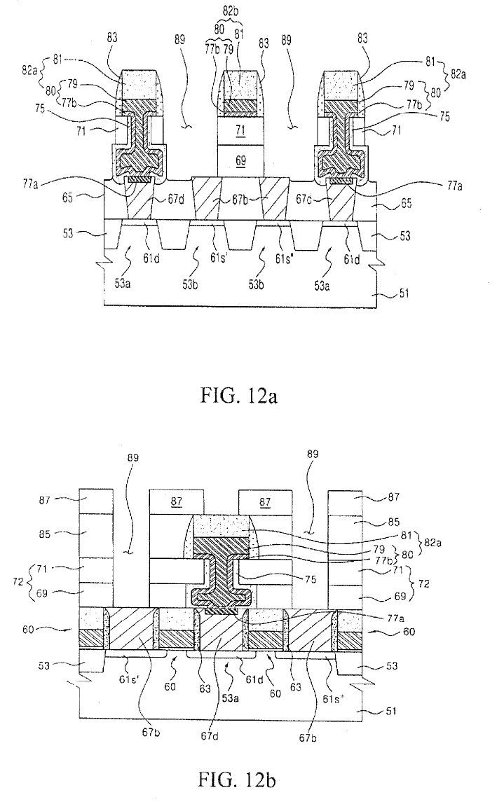

Referring to FIGS. 12a and 12b, the third interlayer dielectric layer 85, the upper dielectric layer 71, and the lower dielectric layer 69 may be patterned to form preliminary storage node contact holes 89 using an anisotropic etching process. The full top surface or edges of the second conductive pads 67b may not be exposed by preliminary contact holes 89 as illustrated in FIGS. 12a and 12b.

According to some embodiments, a second photo-resist layer 87 may be formed on the third interlayer dielectric layer 85 to be used as an etch mask to form the preliminary storage node contact holes 89. The second photo-resist layer 87 may be patterned to expose portions of the third interlayer dielectric layer 85.

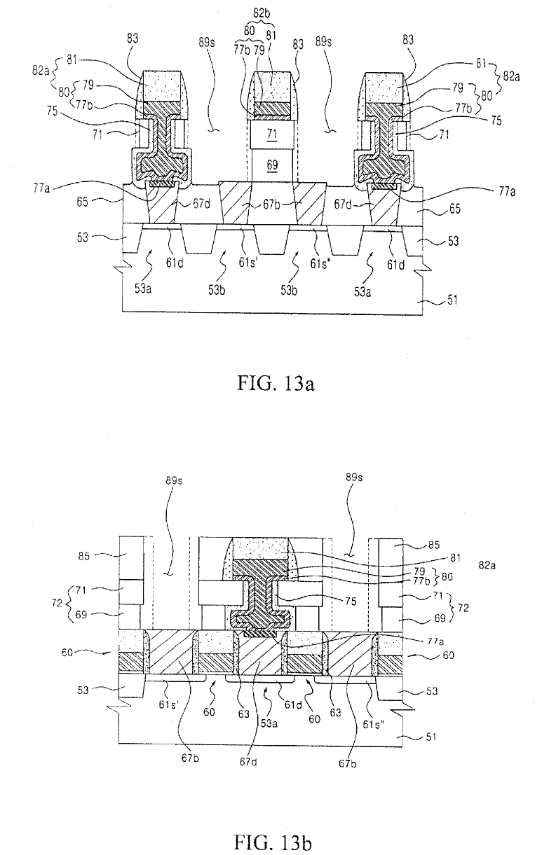

Referring to FIGS. 13a and 13b, to maximize the exposed areas of the surface of the second conductive pads 67b and to remove contaminants in the preliminary storage node contact holes 89, a wet etching process may be used. The wet etching process may employ an oxide film etching solution that contains hydrofluoric acid. As a result, the third interlayer dielectric layer 85, the upper dielectric layer 71 and the lower dielectric layer 69 may be isotropically etched, thereby forming enlarged buried contact holes 89s extended from the preliminary contact holes 89, indicated as dotted lines.

According to some embodiments, the second photo-resist pattern 87 may be removed prior to performing the wet etching process.

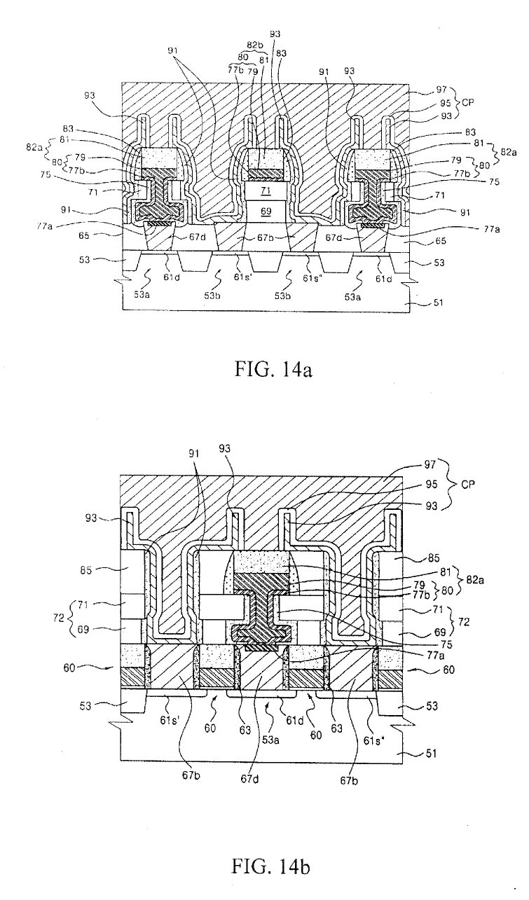

Referring to FIGS. 14a and 14b, known techniques are performed to complete a cell capacitor CP which includes a capacitor bottom electrode 93, a capacitor dielectric 95 and a capacitor upper electrode 97 in the buried contact holes 89s. In detail, buried contact spacers 91 may be formed on the sidewalls of the enlarged buried contact holes 89s prior to formation of the cell capacitor CP.

Barrier metal patterns 77b may be exposed because of over etch of the upper dielectric layer 71 when the enlarged buried contact holes 89s are formed. In this case, the buried contact spacers 91 may prevent the bit lines 80 from being connected electrically with conductive layers such as the capacitor upper electrode 97.

According to the embodiment described above, the etch shield layer 75 prevents the first conductive pads 67d from being exposed during the formation of the buried contact holes 89s. Therefore, with this feature of the present invention, etchant can be prevented from contacting the first conductive pads 67d, particularly the metal silicide layer formed in the first conductive pads and forming voids on the conductive pads as explained in the further below.

Also, the buried contact spacer 91 may extend into the first interlayer dielectric layer 65 adjacent the conductive pad 67d, thereby covering upper sidewalls of the conductive pad 67. Thus, the buried contact spacer 91 prevents the conductive pad from being exposed while the buried contact hole 89s are formed.

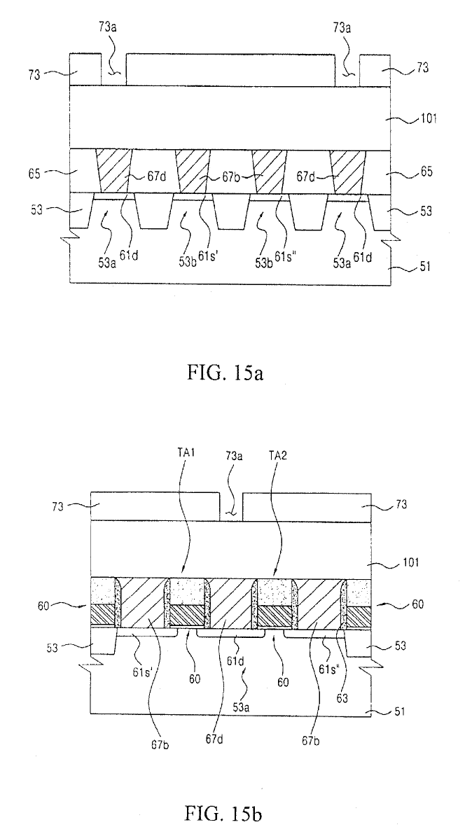

FIGS. 15a through 19a are cross-sectional views corresponding to line I-I′ of FIG. 6 illustrating a manufacturing method according to some other embodiments of the invention. FIGS. 15b through 19b are cross-sectional views corresponding to line II-II′ of FIG. 6 illustrating a manufacturing method according to some other embodiments of the invention.

Referring to FIGS. 15a and 15b, a second interlayer dielectric layer 101 is formed on a first interlayer dielectric layer 65 and first and second conductive pads 67d and 67b. The second interlayer dielectric layer 101 may be a single-layer dielectric layer. For example, the second interlayer dielectric layer 101 may be formed of a BPSG layer or a single-layer silicon oxide layer such as a high-density plasma (HDP) oxide layer. Then, a first photoresist pattern 73 may be formed on the second interlayer dielectric layer 101.

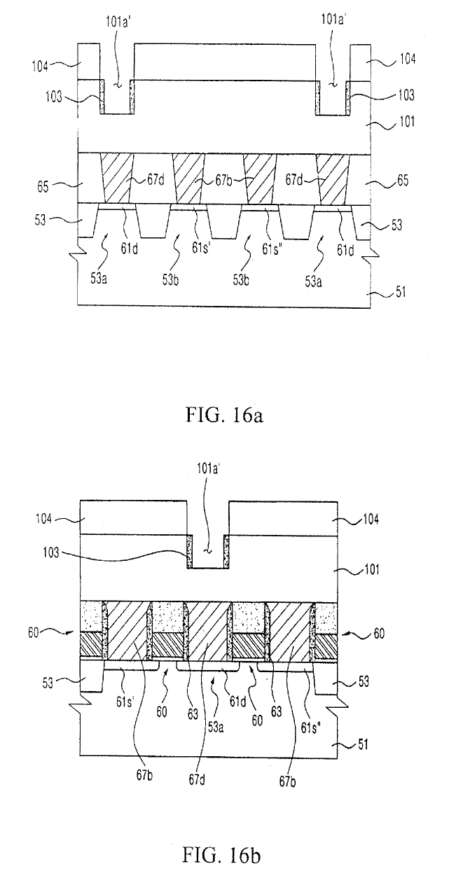

Referring to FIGS. 16a and 16b, the second interlayer dielectric layer 101 is partially etched using the first photoresist pattern 73 as an etching mask to form upper contact holes 101a′ overlying the first conductive pads 67d. Auxiliary contact spacers 103 are formed on the sidewalls of the upper contact holes 101a′ after the first photoresist pattern 73 is removed. The auxiliary contact spacers 103 are formed to have an etch selectivity with respect to the second interlayer dielectric layer 101. For example, the auxiliary contact spacers 103 may be silicon nitride if the second interlayer dielectric layer 101 is silicon oxide.

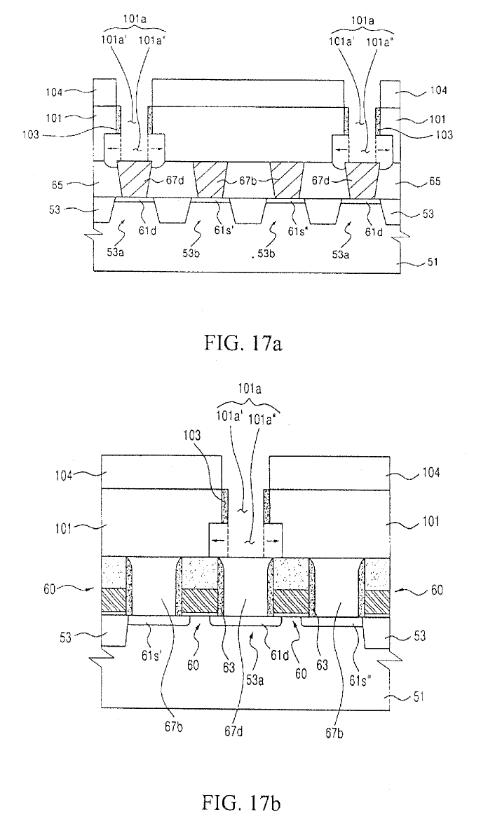

Referring to FIGS. 17a and 17b, an additional photoresist pattern 104 is formed over the semiconductor substrate 51 having the auxiliary contact spacers 103. The second interlayer dielectric layer 101 is then etched, (either dry or wet etching), using the additional photoresist pattern 104 and the auxiliary contact spacers 103 as etching masks. As a result, preliminary lower contact holes are formed to have sidewall profiles initially as shown with the dotted lines in FIG. 17a and FIG. 17b. Then, the second interlayer dielectric layer 101 may be isotropically etched using the additional photoresist pattern 104 and the auxiliary contact spacers 103 as etch masks. The isotropic etch process may include a wet etch process. As a result, lower contact holes 101a″, similar to the lower contact holes 72a″ in FIGS. 9a and 9b, are formed under the upper contact holes 101a′. As illustrated, the lower contact holes 101a″ may be formed to expose the top surface and, in some embodiments, the upper sidewalls of the first conductive pads 67d. The auxiliary contact spacers 103 prevent the width of the upper contact hole 101a′ from being increased during formation of the lower contact hole 101a″. Accordingly, a direct contact hole, i.e., bit line contact hole, 101a comprising the upper contact hole 101a′ and the lower contact hole 101a″ can be formed.

According to some embodiments, the second interlayer dielectric layer 101 may be formed of a material with a graded impurity concentration. For instance, the material may be BPSG with a graded boron concentration. For example, a lower part of the interlayer dielectric layer 101 has a boron concentration higher than that of the upper part of the interlayer dielectric layer 101 such that the lower part of the interlayer dielectric layer 101 has a higher wet etching rate than the upper part of the interlayer dielectric layer 101 if the interlayer dielectric layer is exposed to an etching solution such as one including hydrofluoric acid (HF solution). With such interlayer dielectric layer 101, direct contact holes similar to the direct contact hole 101a discussed above may be formed. In this case, the auxiliary contact spacers 103, therefore, may not be required. The etching rate of the second interlayer dielectric layer 101 may vary in accordance with the boron concentration.

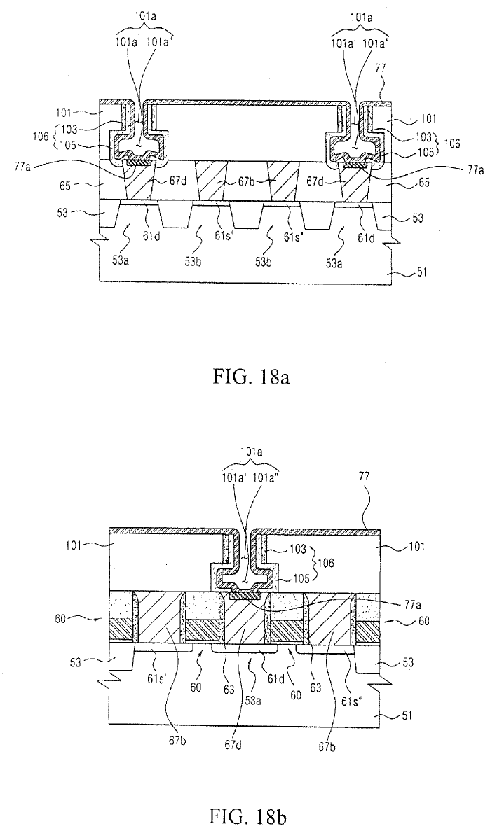

Referring to FIGS. 18a and 18b, an etch shield layer 105 is then formed to cover sidewalls of the direct contact hole 101a, the peripheral regions of the top surface of the first conductive pads 67d, and, in some embodiments, at upper sidewalls of the first conductive pads 67d after the additional photoresist pattern 104 is removed. Thus, formation of the etch shield layer 105 is similar to the process steps discussed above with respect to FIGS. 10a and 10b. As a result, a direct contact spacer 106 including the auxiliary contact spacers 103 and the etch shield layer 105 is formed. In this case, the direct contact spacer 106 covers the sidewall of the direct contact hole 101a formed through the second dielectric layer 101 differently from the embodiment discussed above. Next, a barrier metal layer 77 is formed over the semiconductor substrate 51 having the direct contact spacers 106. A metal silicide layer 77a may be formed over the upper surface of the first conductive pads 67d while the barrier metal layer 77 is formed.

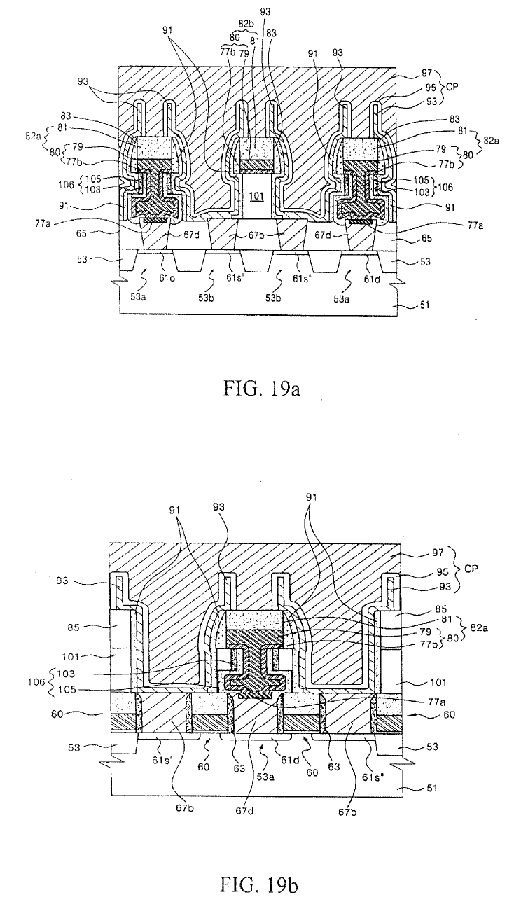

Referring to FIGS. 19a and 19b, processing steps similar to processing steps illustrated in FIGS. 11a through 14a are performed to form structures disclosed in FIGS. 19a and 19b. For example, a wiring metal layer and a wiring capping layer are formed over the barrier metal layer 77. The wiring metal layer may be formed to fill the direct contact hole 101a of FIG. 18a. The wiring metal layer may include a metal film such as a tungsten film and the wiring capping layer may include an insulating film such as a silicon nitride layer. The wiring metal layer and the wiring capping layer are then patterned to expose portions of the second interlayer dielectric layer 101, thereby forming a first bit line pattern 82a including a barrier metal layer pattern 77b, a bit line 80, a bit line capping pattern 81. A third interlayer dielectric layer 85 is then formed on the exposed portions of the second interlayer dielectric layer 101. The first interlayer dielectric layer 85 and the second interlayer dielectric layer 101 may be etched to form preliminary contact holes over the second conductive pads 67b. The full top surface of the second conductive pads 67b may not be exposed by the preliminary contact holes.

In order to maximize the exposed areas of the surface of the second conductive pads 67b and to remove contaminants in the preliminary contact holes, a wet etching process may be used. The wet etching process may include an oxide film etching solution that contains hydrofluoric acid. As a result, the third interlayer dielectric layer 85 and the interlayer dielectric layer 101 may be isotropically etched, thereby forming enlarged buried contact holes (not illustrated).

A cell capacitor CP similar to the cell capacitor CP shown in FIG. 14a may then be formed in the enlarged buried contact holes. The cell capacitor CP includes a capacitor bottom electrode 93, a capacitor dielectric 95 and a capacitor upper electrode 97, which are sequentially stacked. Buried contact spacers 91 may be formed on the sidewalls of the enlarged buried contact holes prior to formation of the cell capacitor CP for the reasons discussed with respect to FIG. 14a.

Therefore, according to embodiments exemplarily described above, a first interlayer dielectric layer having first conductive pads therein is provided. The first interlayer dielectric layer and first conductive pads are then covered with a second interlayer dielectric layer and a wiring pattern is arranged over the second interlayer dielectric layer. The wiring pattern is electrically connected with the first conductive pads through a contact hole that having upper and lower portions wherein, in some embodiments, the lower portion is wider than the upper portion.

According to some embodiments discussed with reference to FIGS. 6a through 11a, a second interlayer dielectric layer includes two dielectric layers having different etching rates. According to other embodiments, the second interlayer dielectric layer is a single dielectric layer. In this case, the direct contact hole may be formed by using an auxiliary contact spacer such as the spacer 103 or using the interlayer dielectric layer having a graded impurity concentration as discussed above.

According to the embodiment described above, the etch shield layer 105 prevents etchant from contacting the first conductive pads 67d, particularly the metal silicide layer formed in the first conductive pads 67d and/or forming voids on the first conductive pads 67d. In further detail, in the prior art as discussed in the background, the exposed top end portions of the contact pads 67d adjacent to the pad spacer 9 are vulnerable to chemical attack from the etchant used to form a storage node contact hole. Also, the complicated processing steps to form the pad spacer 9 were necessary to protect the contact pads 67d.

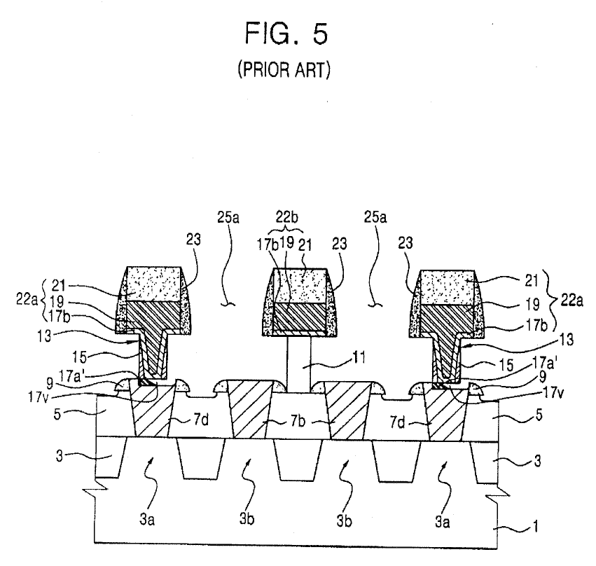

However, with some embodiments of the present invention, by protecting the corners of the first contact pads 67d, i.e., peripheral portions of the top surface of the contact pads 67d and/or the upper sidewalls of the first contact pads 67d with the etch shield layer 75, the voids that were inevitably formed during the prior art methods as illustrated in FIG. 5 can be avoided and, as a result, shorts between the contacts and/or bit lines resulting from such chemical attacks can be effectively prevented. Also, as the pad spacer 9 needs not be formed, the processing steps can be simplified.

The principles of the present invention can be applied to any multi-layer contact structure, which has a similar issue, i.e., a chemical attack on the exposed portion of the lower contact structure as width or diameter of the upper contact structure is smaller than that of the lower contact structure, thereby exposing some portions of the lower contact structure.

Reference throughout this specification to “some embodiments” or “an embodiment” means that a particular feature, structure, or characteristic described in connection with the embodiment is included in at least one embodiment of the present invention. Thus, the appearances of the phrases “some embodiment” or “an embodiment” in various places throughout this specification are not necessarily all referring to the same embodiment. Furthermore, the particular features, structures, or characteristics may be combined in any suitable manner in one or more embodiments.

Although various preferred embodiments have been disclosed herein for illustrative purposes, those skilled in the art will appreciate that various modifications, additions, and substitutions are possible without departing from the scope and spirit of the invention as provided in the accompanying claims. For example, various operations have been described as multiple discrete steps performed in a manner that is most helpful in understanding the invention. However, the order in which the steps are described does not imply that the operations are order-dependent or that the order that steps are performed must be the order in which the steps are presented.

While the invention has been particularly shown and described with reference to exemplary embodiments thereof, it will be understood by those of ordinary skill in the art that various changes in form and details may be made therein without departing from the spirit and scope of the present invention as defined by the following claims.

1. A method of forming a semiconductor device, the method comprising:
forming an insulation layer over a semiconductor substrate, the insulation layer having a conductive pad formed therein;
forming a dielectric layer on the insulation layer and the conductive pad;
etching a region of the dielectric layer to form a contact hole overlying the conductive pad, the contact hole exposing top corners of the conductive pad; and
forming an etch shield layer within the contact hole, the etch shield layer covering the top corners of the conductive pad.

2. The method of claim 1, wherein the contact hole extends into the insulation layer and the etch shield layer covers an upper sidewall of the conductive pad.

3. The method of claim 2, wherein the conductive pad has a silicide layer formed thereon and the etch shield layer extends below the silicide layer.

4. The method of claim 1, wherein the dielectric layer comprises an upper dielectric layer and a lower dielectric layer and wherein etching the dielectric layer comprises:
etching the upper dielectric layer and the lower dielectric layer using an anisotropic etch to form a preliminary contact hole extending through the upper and lower dielectric layers, the preliminary contact hole exposing a portion of the conductive pad; and
isotropically etching the lower dielectric layer to enlarge the preliminary contact hole.

5. The method of claim 4, wherein the upper dielectric layer has an etch selectivity with respect to the lower dielectric layer.

6. The method of claim 1, wherein etching a region of the dielectric layer comprises:
etching an upper portion of the dielectric layer to form an upper contact hole;
forming an auxiliary contact spacer on sidewalls of the upper contact hole; and
etching a lower portion of the dielectric layer using the auxiliary contact spacer as an etch mask.

7. A method of fabricating a semiconductor device, the method comprising:
forming an insulation layer over a semiconductor substrate, the insulation layer having a conductive pad formed therein;
forming a dielectric layer over the insulation layer and the conductive pad;
etching a first portion of the dielectric layer to form an upper contact hole above the conductive pad, the upper contact hole having a width smaller than an upper width of the conductive pad;
etching a second portion of the dielectric layer to form a lower contact hole below the upper contact hole and over the conductive pad, the lower contact hole having a width greater than the upper width of the conductive pad to expose top corners of the conductive pad; and
forming an etch shield layer to cover the sidewalls of the upper contact hole and the lower contact hole, the etch shield layer covering the top corners of the conductive pad.

8. The method of claim 7, wherein forming the dielectric layer comprises:
forming a lower dielectric layer over the insulation layer and the conductive pad; and
forming an upper dielectric layer over the lower dielectric layer, wherein etching the first portion comprises etching the upper dielectric layer and etching the second portion comprises etching the lower dielectric layer.

9. The method of claim 8, wherein etching the lower dielectric layer comprises isotropically etching the lower dielectric layer.

10. The method of claim 8, wherein etching the lower dielectric layer comprises etching an upper portion of the insulation layer adjacent to the conductive pad to expose an upper sidewall of the conductive pad.

11. The method of claim 10, further comprising forming a silicide layer on a top portion of the conductive pad, the recess extending below the silicide layer.

12. The method of claim 8, wherein the upper dielectric layer has an etch selectivity with respect to the lower dielectric layer.

13. The method of claim 12, wherein the upper dielectric layer is boro-phospho-silicate glass (BPSG) including a first boron concentration and the lower dielectric layer is BPSG including a second boron concentration, wherein the first boron concentration is less than the second boron concentration.

14. The method of claim 7, wherein the dielectric layer comprises an upper region and a lower region, etching the first portion comprises etching the upper region, and etching the second portion comprises etching the lower region.

15. The method of claim 14, further comprising forming a spacer on sidewalls of the upper contact hole prior to etching the lower region.

16. The method of claim 14, wherein the dielectric layer has a graded impurity concentration so that the lower region etches faster than the upper region.

17. The method of claim 16, wherein the graded impurity concentration comprises a graded boron concentration in a boro-phospho-silicate glass (BPSG) layer.

18. A method of manufacturing a semiconductor device comprising:
forming an active area on a semiconductor substrate;
forming an insulation layer on the active area, the insulation layer having conductive pad formed therein;
forming a lower dielectric layer on the insulation layer and the contact pad;
forming an upper dielectric layer on the lower dielectric layer;
etching the upper dielectric layer to form an upper contact hole overlying the conductive pad, wherein the upper contact hole has a width that is less than the width of the conductive pad;
etching the lower dielectric layer to form a lower contact hole overlying the conductive pad and below the upper contact hole, wherein the lower contact hole has a width that is greater than the width of the conductive pad;
forming an etch shield layer so as to cover the sidewalls of the upper contact hole and to cover top corners of the conductive pad, the etch shield layer having an opening exposing a portion of the conductive pad;
forming a barrier metal layer over the etch shield layer;
forming a wiring metal layer over the barrier metal layer, wherein the wiring metal layer fills the upper and lower contact holes; and
forming a wiring capping layer over the wiring metal layer.

19. The method of claim 18, further comprising:
patterning the wiring capping layer, the wiring metal layer and the barrier metal layer to form bit line patterns each including a barrier metal layer pattern, a bit line, and a bit line capping pattern, which are sequentially stacked;
forming a bit line pattern spacer disposed on the sidewalls of the bit line pattern; and
forming a third interlayer dielectric layer on the upper dielectric layer.

20. The method of claim 18, wherein the barrier metal layer comprises a titanium material.

21. The method of claim 18, wherein the wiring metal layer comprises a tungsten material.

22. A method of manufacturing a semiconductor device comprising:
forming an isolation layer on a semiconductor substrate, the isolation layer defining a plurality of first active areas and a plurality of second active areas;
forming an insulation layer on the semiconductor substrate having the plurality of first and second active areas defined thereon;
patterning the insulation layer to form a plurality of first contact holes exposing the first active areas;
patterning the insulation layer to form a plurality of second contact holes exposing the second active areas;
forming a plurality of first conductive pads in the first contact holes;
forming a plurality of second conductive pads in the second contact holes;
forming a lower dielectric layer on the insulation layer and the first and second contact pads;
forming an upper dielectric layer on the lower dielectric layer;
etching the upper dielectric layer to form a plurality of upper contact holes overlying the first conductive pads;
etching the lower dielectric layer to form a plurality of lower contact holes overlying the first conductive pads and under the upper contact holes, wherein the lower contact hole has a width that is greater than an upper width of the first conductive pad;
forming an etch shield layer so as to cover the sidewalls of the upper contact holes and top corners of the first conductive pads;
forming a barrier metal layer over the etch shield layer;
forming a wiring metal layer over the barrier metal layer, wherein the wiring metal layer pattern fills the upper and lower contact holes;
forming a wiring capping layer over the wiring metal layer;
patterning the wiring capping layer, the wiring metal layer, the barrier metal layer to form bit line patterns overlying the etch shield layer, the bit line patterns each comprising a barrier metal layer pattern, a bit line, a bit line capping pattern, which are sequentially stacked;
forming a third interlayer dielectric layer on the upper dielectric layer;
etching the third interlayer dielectric layer, the upper dielectric layer, and the lower dielectric layer between the bit line patterns, so as to expose the second conductive pads, thereby forming a plurality of buried contact holes; and
forming a plurality of cell capacitors in the buried contact holes.

23. The method of claim 22, wherein the upper dielectric layer has an etch selectivity with respect to the lower dielectric layer.

24. The method of claim 22, wherein etching the third interlayer dielectric layer, the upper dielectric layer, and the lower dielectric layer comprises:
forming a plurality of preliminary buried contact holes by anistropically etching the third interlayer dielectric layer, the upper dielectric layer, and the lower dielectric layer; and
forming the plurality of buried contact holes from the preliminary buried contact holes by isotropically etching the third interlayer dielectric layer, the upper dielectric layer, and the lower dielectric layer.

25. The method of claim 24, wherein hydrofluoric acid solution is used to isotropically etch the third interlayer dielectric layer, the upper dielectric layer, and the lower dielectric layer.

26. The method of claim 22, further comprising forming a plurality of buried contact spacers on the sidewalls of the buried contact holes prior to forming the cell capacitors.

27. A method of forming a semiconductor device, the method comprising:
forming an insulation layer over a semiconductor substrate, the insulation layer having a conductive pad formed therein;
forming a dielectric layer on the insulation layer and the conductive pad;
etching a region of the dielectric layer to form a contact hole overlying the conductive pad, the contact hole exposing a peripheral portion of a top surface of the conductive pad; and
forming an etch shield layer within the contact hole,
wherein the etch shield layer covers the peripheral region of the top surface of the conductive pad.

28. A semiconductor device comprising:
an active area defined on a semiconductor substrate;
an insulation layer disposed on the semiconductor substrate;
a conductive pad disposed within the insulation layer and overlying the active area;
a dielectric layer disposed on the insulation layer, the dielectric layer having a contact hole exposing top corners of the conductive pad; and
an etch shield layer formed within the contact hole, the etch shield layer disposed to cover the top corners of the conductive pad.

29. The device of claim 28, wherein the dielectric layer comprises a lower region and an upper region.

30. The device of claim 29, wherein the upper region of the dielectric layer has an etch selectivity with respect to the lower region thereof.

31. The device of claim 28, wherein the conductive pad further comprises a silicide layer having a defined thickness and the etch shield layer extends into the insulation layer below the silicide layer to cover an upper sidewall of the conductive pad.

32. The device of claim 28, wherein the dielectric layer comprises:
a lower dielectric layer disposed on the insulation layer, the lower dielectric layer having a lower contact hole overlying the conductive pad, the lower contact hole having a width that is greater than an upper width of the conductive pad; and
an upper dielectric layer disposed on the lower dielectric layer, the upper dielectric layer having an upper contact hole over the lower contact hole.

33. The device of claim 32, wherein the upper contact hole has a width that is smaller than the width of the conductive pad.

34. The device of claim 32, wherein the upper dielectric layer comprises an etch selectivity with respect to the lower dielectric layer.

35. The device of claim 32, further comprising:
a barrier metal layer disposed on the etch shield layer;
a wiring metal layer pattern disposed on the barrier metal layer;
a bit line capping pattern disposed on the wiring metal layer pattern; and
a bit line pattern spacer disposed on the sidewalls of the wiring metal layer pattern and the bit line capping pattern.

36. A semiconductor device comprising:
an active area pattern on a semiconductor substrate, wherein the active area pattern defined by an isolation layer comprises:
a plurality of first active areas; and
a plurality of second active areas;
an insulation layer disposed on the first and second active areas, the isolation layer having a plurality of first conductive pads overlying the first active areas and a plurality of second conductive pads overlying the second active areas;
a dielectric layer disposed on the insulation layer, the dielectric layer having a bit line contact hole exposing top corners of the conductive pad;
an etch shield layer formed within the bit line contact hole, the etch shield layer disposed to cover the top corners of the conductive pad;
a bit line pattern disposed on the etch shield layer;
a third interlayer dielectric layer disposed on the upper dielectric layer;
a plurality of buried contact holes disposed on the second conductive pads, the plurality of buried contact holes extending through the third interlayer dielectric layer, the upper dielectric layer and the lower dielectric layer; and
a plurality of cell capacitors formed in the plurality of buried contact holes.

37. A semiconductor device comprising:
an active area defined on a semiconductor substrate by a device isolation layer;
an insulation layer disposed on the semiconductor substrate;
a conductive pad disposed within the insulation layer and overlying the active area;
a dielectric layer disposed on the insulation layer, the dielectric layer having a contact hole formed therein; the contact hole having a with greater than that of the conductive pad and
an etch shield layer formed within the contact hole, the etch shield layer having an opening exposing a center region of the conductive pad and to cover a peripheral region of the conductive pad.

38. The device of claim 37, wherein the dielectric layer comprises:
a lower dielectric layer disposed on the insulation layer, the lower dielectric layer having a lower contact hole overlying the conductive pad, the lower contact hole having a width that is greater than an upper width of the conductive pad; and
an upper dielectric layer disposed on the lower dielectric layer, the upper dielectric layer having an upper contact hole over the lower contact hole, wherein the upper contact hole has a width smaller than the upper width of the conductive pad.
